(19) United States
(12) Patent Application Publication
(10) Pub. No.: US 2007/0238318 A1
(43) Pub. Date: Oct. 11, 2007

(54) Method of fabricating a semiconductor device

(75) Inventors: Hui-Lin Hsu, Taipei City (TW); Tri-Rung Yew, Hsinchu City (TW); Po-Yuan Lo, Taipei City (TW); Zing-Way Pei, Taichung City (TW)

Correspondence Address: QUINTERO LAW OFFICE, PC, 2210 MAIN STREET, SUITE 200, SANTA MONICA, CA, 90405, US

(73) Assignee: INDUSTRIAL TECHNOLOGY RESEARCH INSTITUTE, HSINCHU (TW)

(21) Appl. No.: 11/510,294

(22) Filed: Aug. 25, 2006

(30) Foreign Application Priority Data
Apr. 6, 2006 (TW) TW95112104

(51) Int. Cl. H01L 21/31; H01L 21/469

(52) U.S. Cl. 438/780; 257/E51.007

(57) ABSTRACT

A method of fabricating a semiconductor device is provided. The method of fabricating the semiconductor device comprises a substrate. A polyacrylonitrile (PAN) powder is dissolved in a solvent and the solvent is heated to form a PAN solution. The PAN solution is cooled down and the PAN solution is then formed on the substrate. The PAN solution is allowed to stand and the solvent in the PAN solution is then removed to form a PAN dielectric layer on the substrate. A patterned conductive layer is formed on the PAN dielectric layer.

### BACKGROUND OF THE INVENTION

1. Field of the Invention

The present invention relates to a fabricating method of a semiconductor, and in particular to a method of fabricating a semiconductor a polyacrylonitrile (C₃H₃N)ₙ, PAN) dielectric layer.

2. Description of the Related Art

Organic thin film transistors (OTFTs) have drawn a lot of considerable in the past due to the advantages of light weight, low cost of fabrication for large area, simple fabrication method, thin profile, and mechanically flexible. Thus, OTFTs are employed in disposable products, radio frequency identification (RFID), smart levels, smart tags or other devices. Semiconductor materials, dielectric materials, and conductive materials with high process compatibility between layers of semiconductor devices are important for current organic thin film developments. Also, low temperature (<200° C.) and simple fabrication processes are needed to meet the requirement of low cost.

OTFTs, however, continue to encounter issues of low carrier mobility and low on/off current ratio (Ion/Ioff), which require high operating voltage to drive the transistors and in turn have high power consumption. As a result, there have been numerous studies on semiconductor materials in order to improve the performance of OTFTs. In addition to working on improving the properties of semiconductor materials to overcome the described limitations, new dielectric materials that can provide high saturation current with low leakage current at low voltage to reduce operating voltage must be developed. Conventional inorganic dielectric materials, however, often require high-temperature chemical vapor deposition (CVD), annealing or oxidation processes which result in high cost and process incompatibility which flexible substrates can't withstand. Furthermore, most inorganic materials are intrinsically rigid and easily breakable. Thus, a novel organic dielectric material which is fabricated by spin-coating, printing or jet printing in low temperature (<200° C.) to prevent high temperature processes and achieve the requirement of low cost is desirable.

A conventional dielectric layer of an organic thin film transistor comprises Polyvinyl alcohol (PVA), Polyvinyl Butyral (PVB), PolyVinylChloride (PVC), PolyStyrene (PS), PolyVinylPhenol (PVP) or PolyMethylMethAcrylate (PMMA).

FIG. 1a is a leakage current versus the applied voltage characteristic of conventional Polyvinyl Butyral (PVB) and Ti(OC₄H₉)₄ used for a dielectric layer of an organic thin film transistor disclosed in US Pat. No. 20050001210A1. PVB and Ti(OC₄H₉)₄ are mixed for the first dielectric layer of an organic thin film transistor; PVP and cyclohexanone solution with 10 wt % of cyclohexanone weight concentration are mixed for the second dielectric layer of an organic thin film transistor. FIG. 1a comprises a leakage current curve of a 300 nm first dielectric and a 400 nm second dielectric layer 111, a leakage current curve of a 200 nm first dielectric and a 500 nm second dielectric layer 112, and a leakage current curve of a 700 nm cyclohexanone solution with 10 wt % of cyclohexanone weight concentration 113. FIG. 1b is a leakage current versus applied electric voltage characteristic of conventional Polyvinyl alcohol (PVA) for a dielectric layer of an organic thin film transistor. FIG. 1b comprises a leakage current curve of PVA 114 and a leakage current curve of cross linked PVA 115. FIG. 1c is a Gate-Source current versus Gate-Source voltage characteristic of conventional PolyMethylMethAcrylate (PMMA) for a dielectric layer of an organic thin film transistor which comprises a leakage current curve of PMMA 116. FIG. 1d is a leakage current versus applied voltage characteristic of conventional PolyVinylPhenol (PVP) for a dielectric layer of an organic thin film transistor which comprises a leakage current curve of 310 nm PVP 117, a leakage current curve of 280 nm cross linked PVP 118, and a leakage current curve of 100 nm SiO₂ 119. The results show 1000˜4 nA/cm² leakage current density with 10V applied voltage and show a high leakage current in conventional dielectric materials of organic thin film transistors.

### BRIEF SUMMARY OF INVENTION

A detailed description is given in the following embodiments with reference to the accompanying drawings.

A method for fabricating a semiconductor device is provided by employing polyacrylonitrile ((C₃H₃N)ₙ, PAN) for a dielectric layer to improve the issues as illustrated. Some embodiments of a semiconductor device fabrication method comprise: providing a substrate; dissolving a PAN powder in a first solvent and heating the solvent to form a PAN solution; cooling down the PAN solution and then forming the PAN solution on the substrate; removing the solvent in the PAN solution and forming a PAN dielectric layer on the substrate, and forming a patterned conductive layer on the PAN dielectric layer.

Some embodiments of a semiconductor device fabrication method comprise: providing a substrate; dissolving a PAN powder in a first solvent and heating the solvent to form a PAN solution; cooling down the PAN solution and then forming the PAN solution on the substrate; removing the solvent in the PAN solution and forming a PAN dielectric layer on the substrate, and forming a patterned conductive layer on the PAN dielectric layer. The method of fabricating a semiconductor device can further comprise: the step of dissolving an organic polymer powder in a second solvent to form an organic polymer solution; forming the organic polymer solution on the substrate; removing the second solvent in the organic polymer solutions and forming an organic polymer layer on the substrate, and the organic polymer layer is between the PAN dielectric layer and the patterned conductive layer before forming the patterned conductive layer.

Some embodiments of a semiconductor device fabrication method comprise: providing a substrate; dissolving a PAN, powder in a first solvent and heating the solvent to form a PAN solution; cooling down the PAN solution and then forming the PAN solution on the substrate; removing the solvent in the PAN solution and forming a PAN dielectric layer on the substrate, and forming a patterned conductive layer on the PAN dielectric layer. The method of fabricating a semiconductor device can further comprise: the step of dissolving an conductive polymer powder in a third solvent to form an conductive polymer solution; forming the conductive polymer solution on the substrate; removing the solvent in the conductive polymer solution and forming a conductive polymer layer on the substrate, and the conductive polymer layer is between the substrate and the PAN dielectric layer before forming the PAN dielectric layer.

The method of the invention may provide a high quality PAN dielectric layer having a 0.1 nA/cm² leakage current density which is lower than conventional PVA, PVB, PVC, PS, PVP, and PMMA. PAN dielectric also has the advantage of low operating voltage because PAN is highly polar with strong inter-chain interactions between nitride groups. Thus PAN may be to a good candidate for use as a gate dielectric in the fabrication of OTFTs due to this important physical property.

An exemplary embodiment of the semiconductor device fabrication method comprises: providing a PAN weight concentration of a PAN solution; a solvent of the PAN solution; a temperature for heating the PAN solution; a standing time after coating the PAN solution, and a baking temperature for controlling the PAN solution to the optimum process. Fabricating the PAN dielectric layer which the leakage current is similar with the conventional furnace SiO₂ layer. The semiconductor device fabrication method of the invention provides a lower cost fabrication process such as spin-coating, inkjet-printing, cast, or roll-to-roll contact printing at low temperature (<200° C.). Superior low leakage current of the 50 nm PAN dielectric layer as low as 0.7 pA (leakage current density is 0.1 nA/cm²) with 10V applied voltage, which is compatible with the 100 nm furnace SiO₂ dielectric layer (leakage current density is 0.3 nA/cm²), even lower than the 100 nm furnace SiO₂ dielectric layer. Moreover, the PAN dielectric layer according the invention has process compatibility with semiconductor layers such as pentacene or poly(3-hexylthiophene (P3HT). The fabricated organic thin film transistor with PAN as the gate dielectric layer shows superior low leakage current, and the PAN dielectric layer shows process compatibility with flexible substrates (e. q. polyimide, PC or PET), and is particularly applicable to organic thin film transistors.

### BRIEF DESCRIPTION OF DRAWINGS

The invention can be more fully understood by reading the subsequent detailed description and examples with references made to the accompanying drawings, wherein:

FIG. 1a is a leakage current versus applied voltage characteristic of conventional Polyvinyl Butyral (PVB) and (Ti(OC₄H₉)₄) for use in a dielectric layer of an organic thin film transistor.

FIG. 1b is a leakage current versus applied voltage characteristic of conventional Polyvinyl alcohol (PVA) for use in a dielectric layer of an organic thin film transistor.

FIG. 1c is a Gate-Source current versus Gate-Source voltage characteristic of conventional PolyMethylMethAcrylate (PMMA) for use in a dielectric layer of an organic thin film transistor.

FIG. 1d is a leakage current versus applied voltage characteristic of conventional PolyVinylPhenol (PVP) for use in a dielectric layer of an organic thin film transistor.

FIGS. 2a to 2c, FIGS. 3a to 3b, FIGS. 4a to 4b and FIGS. 5a to 5c show crosssections of preferred embodiments of the process of fabricating a semiconductor device.

FIGS. 2a to 2c show crosssections of a first embodiment of the process of fabricating a semiconductor device.

FIGS. 3a to 3b show crosssections of a second embodiment of the process of fabricating a semiconductor device.

FIGS. 4a to 4b show crosssections of a third embodiment of the process of fabricating a semiconductor device.

FIGS. 5a to 5c show crosssections of a fourth embodiment of the process of fabricating a semiconductor device.

FIG. 6 is a process chart of fabricating a PAN dielectric layer of a semiconductor device.

FIG. 7 is a leakage current versus applied voltage characteristic comparison of a PAN dielectric layer and a conventional SiO₂ dielectric layer.

FIG. 8a is a drain-current (Id) versus drain-voltage (Vd) characteristic of a fabricated organic thin film transistor (channel width (W)/channel length (L)=100 μm/100 μm) of PAN for a gate dielectric layer on an n-doped substrate (not shown) and poly(3-hexylthiophene) (PH3T) for use in an active layer.

FIG. 8b is a drain-current (Id) versus drain-voltage (Vd) characteristic of a fabricated organic thin film transistor (channel width (W)/channel length (L)=100 μm/100 μm) of thermal SiO₂ for a gate dielectric layer on an n-doped substrate and poly(3-hexylthiophene) (PH3T) for use in an active layer.

FIG. 9a is a drain-current (Id) versus drain-voltage (Vd) characteristic comparison of a fabricated organic thin film transistor (channel width (W)/channel length (L)=100 μm/100 μm) with PAN for a gate dielectric layer on an n-doped substrate and pentacene for use in an active layer.

FIG. 9b is a drain-current (Id) versus drain-voltage (Vd) characteristic comparison of a fabricated organic thin film transistor (channel width (W)/channel length (L)=100 μm/100 μm) with thermal SiO₂ for a gate dielectric layer on an n-doped substrate and pentacene for use in an active layer.

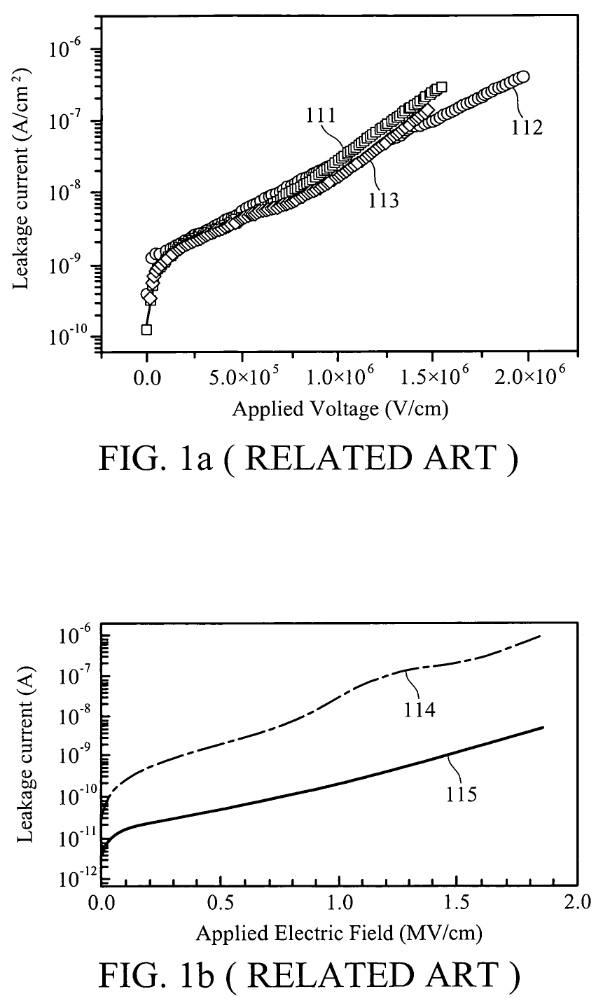

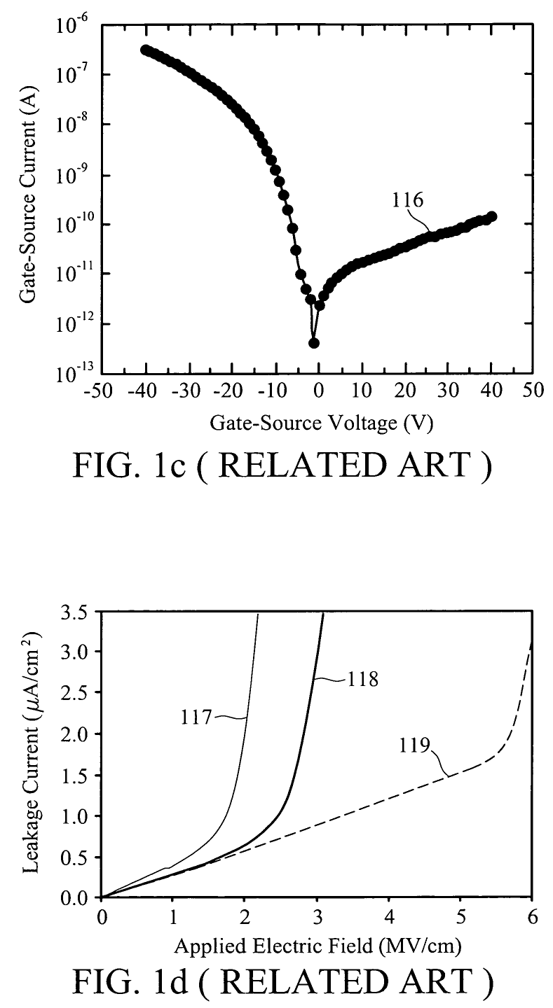

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

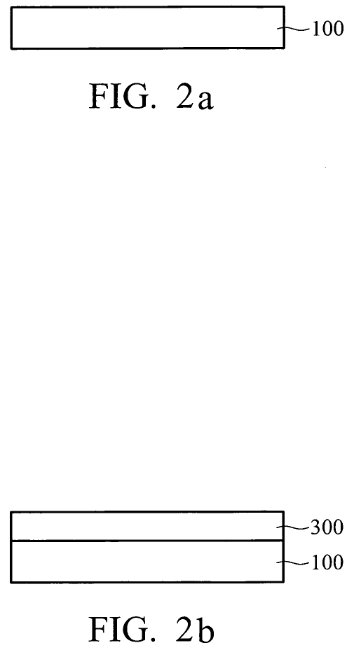

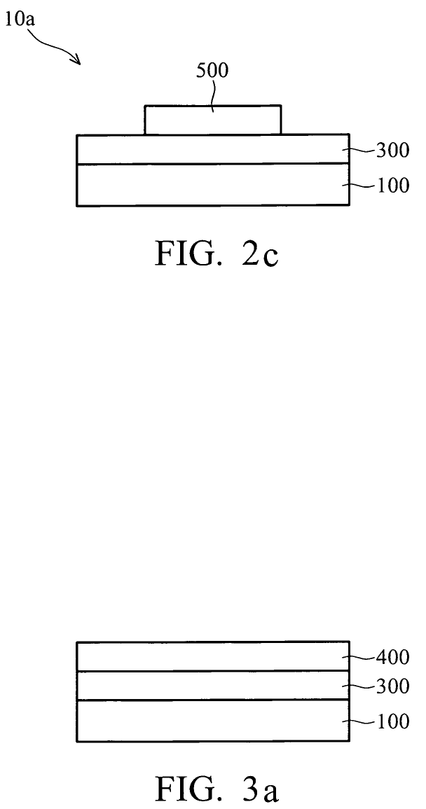

FIGS. 2a to 2c, FIGS. 3a to 3b, FIGS. 4a to 4b and FIGS. 5a to 5c show crosssections of various embodiments of a process of fabricating a semiconductor device. Wherever possible, the same reference numbers are used in the drawing and the description to refer the same or like parts.

Referring to FIG. 2a, the initial step of a first embodiment of forming a Metal-Insulator-Silicon capacitor (MIS) 10a. A substrate 100 is provided. The substrate 100 may comprise inorganic materials, for example, n-doped silicon substrates (resistivity is about 0.008˜0.02 ohm-cm) or glass substrates. The substrate 100 may also comprise organic materials such as polyimide, polycarbonate (PC) or polyethylene terephthalate (PET). In this embodiment, the substrate 100 serves as a semiconductor layer of the MIS; it also serves as a bottom electrode of the MIS.

Referring to FIG. 2b, a polyacrylonitrile (PAN) dielectric layer 300 is formed on the substrate 100. The step of forming the PAN dielectric layer 300 further comprises dissolving a PAN powder (e. g., manufactured by Sigma-Aldrich Chemie GmbH Co.) in a solvent such as propylene carbonate (PC), dimethylformamide (DMF), dimethyl sulfoxide (DMSO), dimethylacetamide, ethylene carbonate (EC), malononitrile, succinonitrile or adiponitrile. Next, the solvent is heated to form PAN solution with PAN concentration of about 0.1 wt % to about 10 wt % (weight percentage). The solvent is heated to a temperature of about 25° C. to 160° C., preferably about 25° C. to 160° C. More preferably about 100° C. to 150° C. Next, the PAN solution is cooled to a temperature of about 25° C. to 50° C., preferably about 20° C. to 40° C. More preferably about 25° C. to 30° C. Then the PAN solution is formed on the substrate 100 by spin-coating, inkjet-printing, casting or roll-to-roll printing. Next, the PAN solution is stands for 1 to 10 min. More preferably for 2 to 5 min. Next, the solvent in the PAN solution is removed by baking. The solvent in the PAN solution is removed at a temperature of about 25° C. to 150° C., preferably at about 50° C. to 150° C. More preferably about 80° C. to 130° C. Next, a PAN dielectric 300 layer is formed on the substrate 100. The process of forming the PAN dielectric layer 300 as described is a low temperature process (<200° C.). The process can prevent the transmutation of the substrate 100 comprising organic or polymer materials formed by a high temperature process. In this first embodiment, the thickness of the PAN dielectric layer 300 is preferably about 40 nm to 60 nm. The PAN dielectric layer 300 serves as an insulator layer of the MIS.

Referring to FIG. 2c, a patterned conductive layer 500 is formed on the PAN dielectric layer 300. A conductive layer is formed by physical vapor deposition (PVD). The patterned conductive layer 500 is formed on the PAN dielectric layer 300 after photolithography and etching. The patterned conductive layer 500 may comprise Au or an alloy thereof. In this embodiment, the patterned conductive layer 500 serves as a metal layer of the MIS; it also serves as a top electrode of the MIS. Thus, fabrication of the Metal-Insulator-Silicon capacitor 10a according to the first embodiment of the invention is complete.

As illustrated, the invention provides a Metal-Insulator-Silicon capacitor 10a comprising a substrate 100. A PAN dielectric layer 300 is formed on the substrate 100. A patterned conductive layer 500 is formed on the PAN dielectric layer 300.

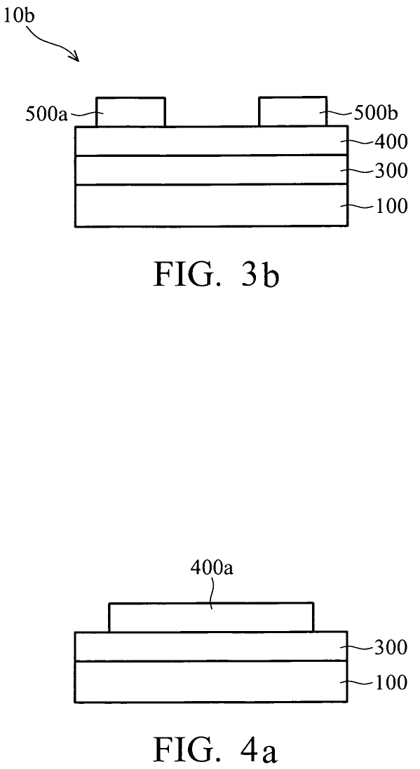

FIGS. 3a to 3b show crosssections of a second embodiment of the process of fabricating an organic thin film transistor 10b. Referring to FIG. 3a, an organic polymer layer 400 is formed on the PAN dielectric layer 300. The step of forming the organic polymer layer 400 further comprises dissolving an organic polymer powder in a solvent such as toluene, dichloromethane, trichloromethane (chloroform) or tetrahydrofuran. Next, an organic polymer solution with the organic polymer concentration of about 0.1 wt % to about 0.5 wt % (weight percentage) is formed. Next, the organic polymer solution is formed on the substrate by spin-coating, inkjet-printing, casting, roll-to-roll printing or evaporation. Next, the solvent in the organic polymer solution is removed by baking and the organic polymer layer 400 is formed on the PAN dielectric layer 300. The organic polymer layer 400 comprises pentacene or poly(3-hexylthiophene) (PH3T) having thicknesses of about 20 to 40 nm or 90 to 110 nm respectively. In this embodiment, the substrate 100, the PAN dielectric layer 300 and the organic polymer layer 400 serve as the gate electrode, the gate dielectric layer and the active layer respectively.

Referring to FIG. 3b, a source 500a/drain 500b is formed on the organic polymer layer 400. A conductive layer is formed by physical vapor deposition (PVD) on the organic polymer layer 400. Then the source 500a/drain 500b is formed on the organic polymer layer 400 after photolithography and etching. The source 500a/drain 500b may comprise Au or an alloy thereof. Thus, fabrication of the organic thin film transistor 10b according to the second embodiment of the invention is complete. The devices of the organic thin film transistor 10b are nearly identical to those of the Metal-Insulator-Silicon capacitor 10a (as shown in FIG. 2a to FIG. 2b) and for simplicity, their detailed description is omitted.

As illustrated, the invention provides an organic thin film transistor 10b comprising a substrate 100. A PAN dielectric layer 300 is formed on the substrate 100. An organic polymer layer 400 is formed on the PAN dielectric layer 300. A source 500a/drain 500b is formed on the organic polymer layer 400.

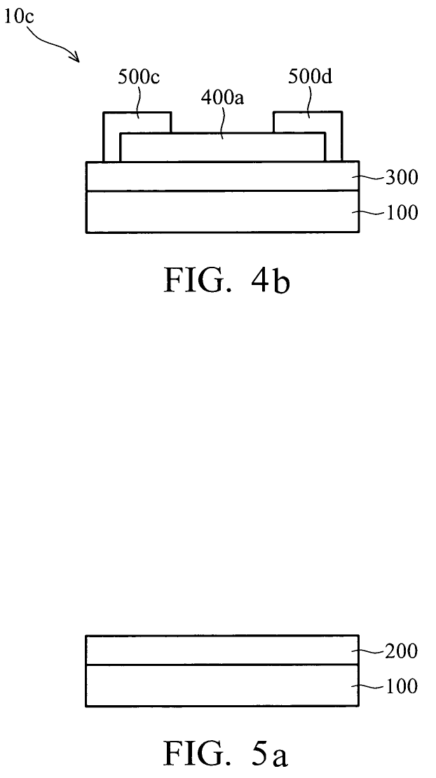

FIGS. 4a to 4b show crosssections of a third embodiment of the process of fabricating an organic thin film transistor 10c. Referring to FIG. 4a, an organic polymer layer 400 is formed on the PAN dielectric layer 300. The step of forming the organic polymer layer 400 further comprises dissolving an organic polymer powder in a solvent such as toluene, dichloromethane, trichloromethane (chloroform) or tetrahydrofuran. Next, an organic polymer solution with the organic polymer concentration of about 0.1 wt % to about 0.5 wt % (weight percentage) is formed. Next, the organic polymer solution is formed on the substrate by spin-coating, inkjet-printing, casting, roll-to-roll printing or evaporation. Next, the solvent in the organic polymer solution is removed by baking and the organic polymer layer 400 is formed on the PAN dielectric layer 300. The organic polymer layer 400 comprises pentacene or poly(3-hexylthiophene) (PH3T) having thicknesses of about 20 to 40 nm or 90 to 110 nm respectively. In this embodiment, the substrate 100, the PAN dielectric layer 300 and the organic polymer layer 400 serve as the gate electrode, the gate dielectric layer and the active layer of the organic thin film transistor 10c respectively.

Referring to FIG. 4b, a source 500a/drain 500b is formed on the organic polymer layer 400. A conductive layer is formed by physical vapor deposition (PVD) on the organic polymer layer 400. Then the source 500a/drain 500b is formed on the organic polymer layer 400 after photolithography and etching. The source 500a/drain 500b may comprise Au or an alloy thereof. Thus, fabrication of the organic thin film transistor 10c according to the third embodiment of the invention is complete. The devices of the organic thin film transistor 10c are nearly identical to those of the Metal-Insulator-Silicon capacitor 10a and the organic thin film transistor 10b (as shown in FIG. 2a to FIG. 2b and FIG. 3a). For simplicity, their detailed description is omitted.

The main difference between the organic thin film transistor 10b and the organic thin film transistor 10c, according to the second and the third embodiments of the invention, is that the active layer is formed in the patterned organic polymer layer 400a, and not completely formed over the PAN dielectric layer 300. The source 500a/drain 500b is formed on part of the patterned organic polymer layer 400a and the PAN dielectric layer 300 not covered by the patterned organic polymer layer 400a. The source 500a/drain 500b covers the sidewall of the patterned organic polymer layer 400a.

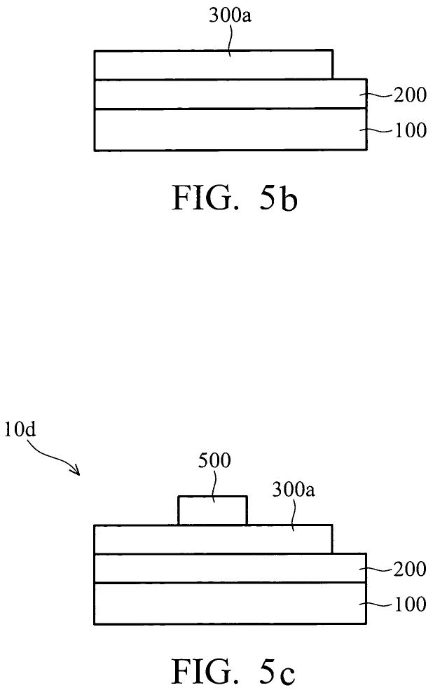

FIGS. 5a to 5c show crosssections of a fourth embodiment of fabricating a Metal-insulator-metal capacitor (MIM) 10d. Referring to FIG. 5a, a conductive polymer layer 200 is formed on the substrate 100. The step of forming the conductive polymer layer 200 further comprises dissolving a conductive polymer powder in a solvent such as isopropylalcohol (IPA) or ethanol. Next, a conductive polymer solution with conductive polymer concentration of about 0.5 wt % to about 20 wt % (weight percentage) is formed. Next, the conductive polymer solution is formed on the substrate by spin-coating, inkjet-printing, casting, roll-to-roll printing or evaporation. Next, the solvent in the conductive polymer solution is removed by baking and the conductive polymer layer 200 is formed on the substrate 100. The conductive polymer layer 200 comprises ethylene glycol-doped poly(3,4-ethylenedioxy-thiophene)/poly(styrenesulfonate) (PEDOT:PSS+EG) and has thicknesses of about 40 to 200 nm. In this embodiment, the conductive polymer layer 200 serves as the bottom electrode of the MIM.

Referring to FIG. 5b, a patterned PAN dielectric layer 300a is formed on the conductive polymer layer 200. The step of forming the patterned PAN dielectric layer 300a further comprises forming the PAN dielectric layer 300 on the, conductive polymer layer 200. The patterned PAN dielectric layer 300a is formed on the conductive polymer layer 200 after photolithography and etching.

Referring to FIG. 5c, the patterned conductive layer 500 is formed on the patterned PAN dielectric layer 300a. A conductive layer is formed by physical vapor deposition (PVD). The patterned conductive layer 500 is formed on the patterned PAN dielectric layer 300a after photolithography and etching. The patterned conductive layer 500 may comprise Au or an alloy thereof. In this embodiment, the patterned conductive layer 500 serves as a metal layer of the MIM; it also serves as a top electrode of the MIM. Thus, fabrication of the Metal-Insulator-Metal capacitor 10d according to the fourth embodiment of the invention is complete.

As illustrated, the invention provides a Metal-Insulator-Metal capacitor 10d comprising a substrate 100. A conductive polymer layer 200 is formed on the substrate 100. A patterned PAN dielectric layer 300a is formed on the conductive polymer layer 200. A patterned conductive layer 500 is formed on the patterned PAN dielectric layer 300a.

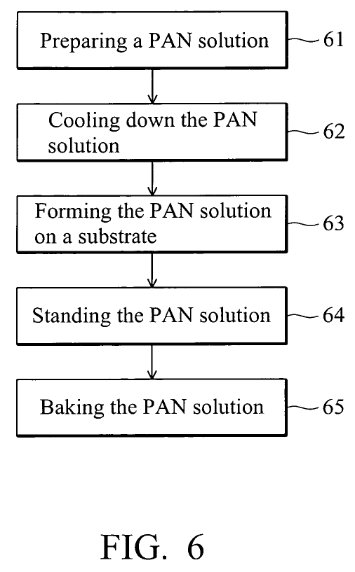

FIG. 6 illustrates a process chart of fabricating a semiconductor device. As shown in step 61, the step of forming the PAN dielectric layer comprises dissolving a PAN powder in a solvent such as propylene carbonate (PC), dimethylformamide (DMF), dimethyl sulfoxide (DMSO), dimethylacetamide, ethylene carbonate (EC), malononitrile, succinonitrile or adiponitrile, the solvent is heated to form a PAN solution with PAN concentration of about 0.1 wt % to about 10 wt % (weight percentage). The solvent is heated to a temperature of about 25° C. to 160° C., preferably about 25° C. to 160° C. More preferably about 100° C. to 150° C. As shown in step 62, the PAN solution is cooled to a temperature of about 25° C. to 50° C., preferably about 20° C. to 40° C. More preferably about 25° C. to 30° C. As shown in step 63, the PAN solution is formed on the substrate 100 by spin-coating, inkjet-printing, casting or roll-to-roll printing. As shown in step 64, preferably the PAN solution stands for 1 to 10 min. More preferably for 2 to 5 min. As shown in step 65, the solvent in the PAN solution is removed by baking. The solvent in the PAN solution is removed at a temperature of about 25° C. to 150° C., preferably about 50° C. to 150° C. More preferably about 80° C. to 130° C. Thus, formation the PAN dielectric 300 layer on the substrate 100 is complete.

The fabricating method of the PAN dielectric 300 layer is illustrated. The PAN dielectric 300 layer serves as the dielectric layer of semiconductor devices. The PAN weight concentration of the PAN solution, the solvent of the PAN solution, the heating temperature region of the PAN solution, the standing time of the PAN solution after coating the PAN solution and control of the baking time are chosen for the optimal process. Fabricating the PAN dielectric layer 300, the leakage current of which, is similar to a conventional furnace SiO₂ layer.

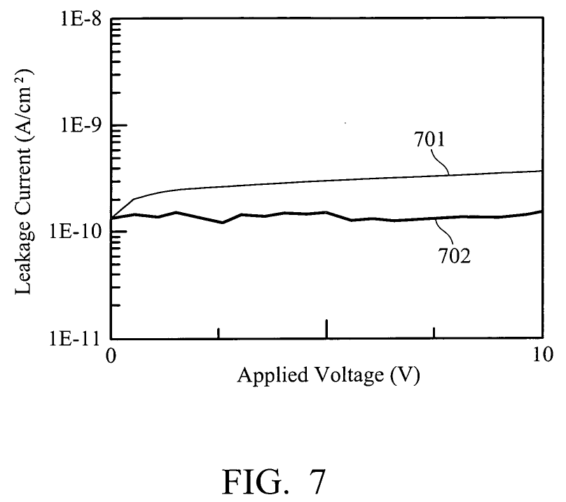

Referring to FIG. 7, a leakage current (Iₗₑₐₖ) versus applied voltage (Vₐₚₚₗ) characteristic of a 50 nm PAN dielectric layer 701 and a 100 nm furnace SiO₂ dielectric layer 702 is illustrated. FIG. 7 shows a 0.7 pA leakage current (leakage current density is 0.1 nA/cm²) of PAN dielectric layer 702 with 10V applied voltage and is compatible with the furnace SiO₂ dielectric layer 702 which has a 0.3 nA/cm² leakage current density, even lower than the furnace SiO₂ dielectric layer 702.

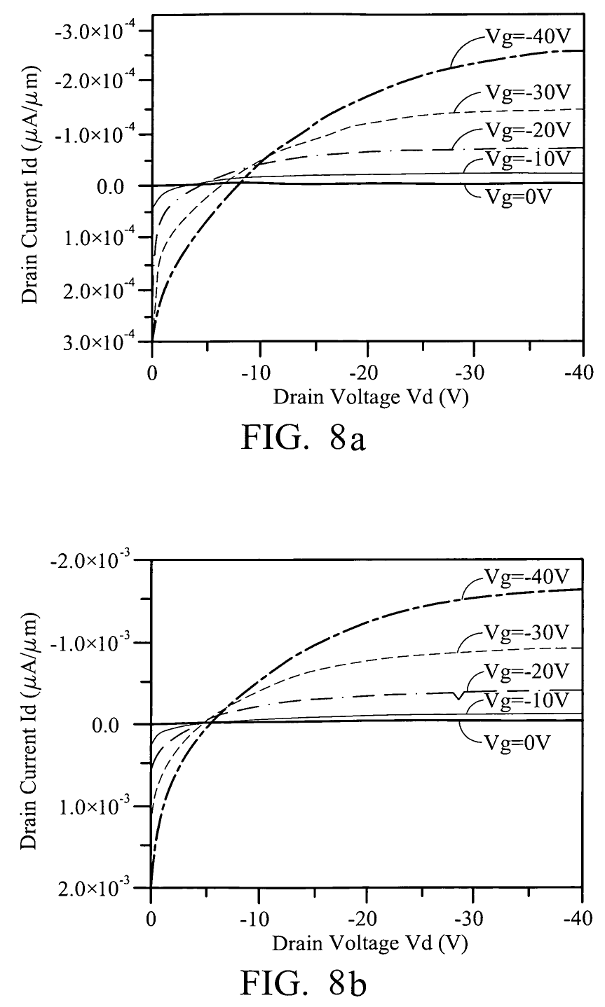

Referring to FIGS. 8a, a drain-current (Id) versus drain-voltage (Vd) characteristic of a fabricated organic thin film transistor (channel width (W)/channel length (L)=100 μm/100 μm) of PAN for a gate dielectric layer on an n-doped substrate (not shown) and poly(3-hexylthiophene) (PH3T) for use in an active layer is illustrated. Referring to FIG. 8b, a thermal SiO₂ was also used as a gate dielectric layer of another fabricated organic thin film transistor (W/L=100 um/100 um) for Id versus Vd characteristic comparison. The drain saturation current (Id_sat), the threshold voltage (Vt); the carrier mobility (μ) and the on/off current ratio (Ion/Ioff) are calculated by the following formula: Id_sat=(W/2L)μC′(Vg-Vt)², where the W, L, μ, C′, Vg, Vt are channel width, channel length, carrier mobility, area capacitance of gate dielectric, gate voltage and threshold voltage, respectively. For the fabricated organic thin film transistor with PAN for the gate dielectric layer and PH3T for the active layer, the Id_sat at −40V Vg, μ, Vt, and Ion/Ioff are 2.5×10⁻³ μA/cm, 5.5×10⁻⁴ cm²V⁻¹s⁻¹, 1.3V, and 6.4×10¹, respectively. As to the fabricated organic thin film transistor with thermal SiO₂ for the gate dielectric layer and PH3T for the active layer for comparison, the Id_sat at −40V Vg, μ, Vt, and Ion/Ioff are 1.5×10⁻³ μA/cm, 2.1×10⁻³ cm²V⁻¹s⁻¹, −5.9V, and 3.4×10¹, respectively. The Id_sat of the fabricated organic thin film transistor with PAN for the gate dielectric layer and PH3T for the active layer is higher than the fabricated organic thin film transistor with thermal SiO₂ for the gate dielectric layer and PH3T for the active layer. It is result form the higher C′ of the fabricated organic thin film transistor with PAN for the gate dielectric layer and PH3T for the active layer. This is because the PAN film (50 nm) is thinner than thermal SiO₂ (100 nm), and has a dielectric constant (k) (k=4.7) higher than that of thermal SiO₂ (k=4). The Ion/Ioff of the fabricated organic thin film transistor with PAN for the gate dielectric layer and PH3T for the active layer (6.4×10¹) has the same order as the fabricated organic thin film transistor with thermal SiO₂ serves as the gate dielectric layer and PH3T for the active layer (3.4×10¹).

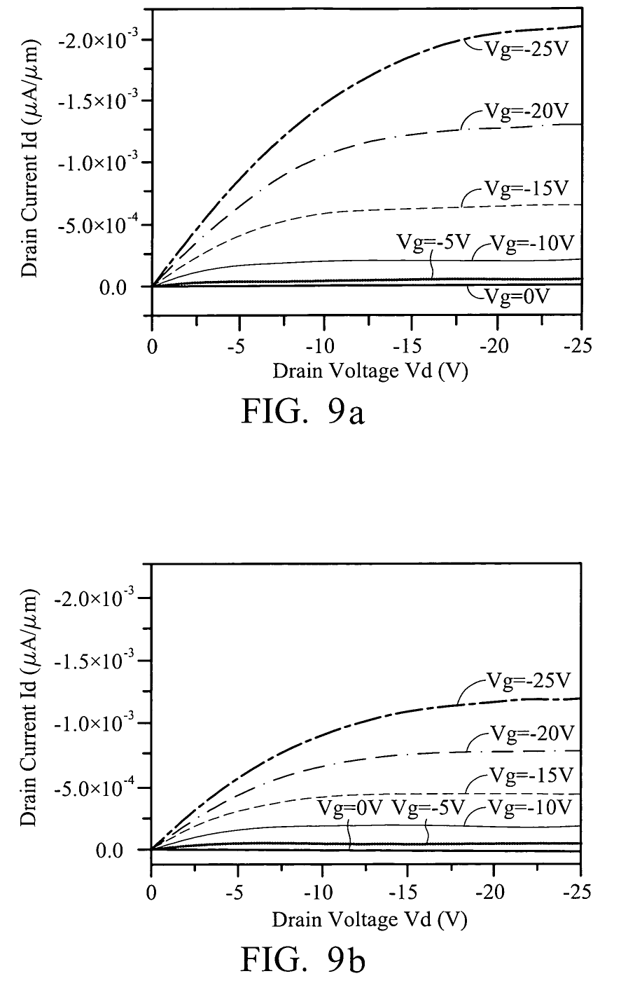

Referring to FIGS. 9a, an Id versus Vd characteristic of a fabricated organic thin film transistor comparison a fabricated organic thin film transistor (W/L=100 um/100 um) with PAN for a gate dielectric layer on an n-doped substrate and pentacene for use in an active layer is illustrated. Referring to FIGS. 9b, a thermal SiO₂ was also used as a gate dielectric layer of another fabricated organic thin film transistor (W/L=100 um/100 um) for Id versus Vd characteristic comparison. For the fabricated organic thin film transistor with PAN for the gate dielectric layer and pentacene for the active layer, the Id_sat at −40V Vg, μ, Vt, and Ion/Ioff are 2.1×10⁻³ μA/cm, 1.4×10⁻² cm²V⁻¹s⁻¹, −0.97V, and 3.14×10³, respectively. As to the fabricated organic thin film transistor with thermal SiO₂ for the gate dielectric layer and pentacene for the active layer for comparison, the Id_sat at −40V Vg, μ, Vt, and Ion/Ioff are 1.25×10⁻³ μA/cm, 3.1×10⁻³ cm²V⁻¹s⁻¹, −0.65V, and 4.55×10³, respectively. The Id_sat of the fabricated organic thin film transistor with PAN for the gate dielectric layer and pentacene for the active layer is higher than the fabricated organic thin film transistor with thermal SiO₂ for the gate dielectric layer and pentacene for the active layer. This results form the higher C′ of the fabricated organic thin film transistor with PAN for the gate dielectric layer and PH3T for the active layer. This is because the thickness of PAN film (50 nm) is thinner than that of thermal SiO₂ (100 nm), and its dielectric constant (k) (k=4.7) is higher than that of thermal SiO₂ (k=4). The Ion/Ioff of the fabricated organic thin film transistor with PAN for the gate dielectric layer and pentacene for the active layer (3.14×10³) has the same order with the fabricated organic thin film transistor with thermal SiO₂ for the gate dielectric layer and pentacene for the active layer (4.55×10³). This proves that the PAN dielectric layer according of the invention shows good performances with low leakage current and low operating voltage and it is suitable for a gate dielectric layer of an organic thin film transistor.

A novel organic dielectric material of the invention, PAN, has advantages of a low temperature fabricating process, low cost, low leakage current, low operating voltage, and process compatibility with flexible substrates. It is particularly applicable for use in organic thin film transistors.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of fabricating a semiconductor device, comprising:
providing a substrate;
dissolving a PAN powder in a first solvent and heating the solvent to form a PAN solution;
cooling down the PAN solution and then forming the PAN solution on the substrate;
removing the solvent in the PAN solution and forming a PAN dielectric layer on the substrate; and
forming a patterned conductive layer on the PAN dielectric layer.

2. The method of fabricating a semiconductor device as claimed in claim 1, wherein the substrate is an inorganic or an organic material.

3. The method of fabricating a semiconductor device as claimed in claim 1, wherein the first solvent comprises propylene carbonate (PC), dimethylformamide (DMF), dimethyl sulfoxide (DMSO), dimethylacetamide, ethylene carbonate (EC), malononitrile, succinonitrile or adiponitrile.

4. The method of fabricating a semiconductor device as claimed in claim 1, wherein the first solvent is heated to a temperature of about 100° C. to 150° C.

5. The method of fabricating a semiconductor device as claimed in claim 1, wherein the first solvent is heated to a temperature of about 50° C. to 160° C.

6. The method of fabricating a semiconductor device as claimed in claim 1, wherein the first solvent is heated to a temperature of about 25° C. to 160° C.

7. The method of fabricating a semiconductor device as claimed in claim 1, wherein PAN solution is cooled to a temperature of about 25° C. to 30° C.

8. The method of fabricating a semiconductor device as claimed in claim 1, wherein the PAN solution is cooled to a temperature of about 20° C. to 40° C.

9. The method of fabricating a semiconductor device as claimed in claim 1, wherein the PAN solution is cooled to a temperature of about 20° C. to 50° C.

10. The method of fabricating a semiconductor device as claimed in claim 1, wherein before removing the first solvent in the PAN solution, further comprising:
allowing the PAN solution to stand for 2 min to 5 min.

11. The method of fabricating a semiconductor device as claimed in claim 10, wherein the PAN solution stands for 1 min to 10 min.

12. The method of fabricating a semiconductor device as claimed in claim 1, wherein the PAN solution is formed on the substrate by spin-coating, inkjet-printing, casting or roll-to-roll printing.

13. The method of fabricating a semiconductor device as claimed in claim 1, wherein the first solvent in the PAN solution is removed at a temperature of about 80° C. to 130° C.

14. The method of fabricating a semiconductor device as claimed in claim 1, wherein the first solvent in the PAN solution is removed at a temperature of about 50° C. to 150° C.

15. The method of fabricating a semiconductor device as claimed in claim 1, wherein the first solvent in the PAN solution is removed at a temperature of about 25° C. to 150° C.

16. The method of fabricating a semiconductor device as claimed in claim 1, wherein the PAN solution has a weight concentration of about 0.1 wt % to about 10 wt % of PAN.

17. The method of fabricating a semiconductor device as claimed in claim 1, wherein the PAN solution has a weight concentration of about 0.25 wt % to about 2 wt % of PAN.

18. The method of fabricating a semiconductor device as claimed in claim 1, wherein the PAN dielectric layer has a thickness of about 40 nm to 60 nm.

19. The method of fabricating a semiconductor device as claimed in claim 1, wherein the patterned conductive layer is a metal layer.

20. The method of fabricating a semiconductor device as claimed in claim 19, wherein the patterned conductive layer comprises Au or Au-alloy.

21. The method of fabricating a semiconductor device as claimed in claim 1, wherein before forming the patterned conductive layer, comprising:
dissolving an organic polymer powder in a second solvent to form an organic polymer solution;
forming the organic polymer solution on the substrate;
removing the second solvent in the organic polymer solutions and forming an organic polymer layer on the substrate; and
the organic polymer layer is between the PAN dielectric layer and the patterned conductive layer.

22. The method of fabricating the semiconductor device as claimed in claim 21, wherein the substrate serves as a gate electrode.

23. The method of fabricating the semiconductor device as claimed in claim 21, wherein the second solvent is toluene, dichloromethane, trichloromethane (chloroform) or tetrahydrofuran.

24. The method of fabricating the semiconductor device as claimed in claim 21, wherein the organic polymer solution is formed on the substrate by spin-coating, inkjet-printing, casting, roll-to-roll printing or evaporation.

25. The method of fabricating the semiconductor device as claimed in claim 21, wherein the organic polymer solution has a weight concentration of about 0.1 wt % to about 0.5 wt % of the organic polymer.

26. The method of fabricating the semiconductor device as claimed in claim 21, wherein the organic polymer layer comprises Pentacene or poly(3-hexylthiophene) (PH3T).

27. The method of fabricating the semiconductor device as claimed in claim 21, wherein the organic polymer layer is Pentacene having a thickness of about 20 nm to 40 nm.

28. The method of fabricating the semiconductor device as claimed in claim 21, wherein the organic polymer layer is poly(3-hexylthiophene) (PH3T) having a thickness of about 90 nm to 10 nm.

29. The method of fabricating the semiconductor device as claimed in claim 21, wherein the patterned conductive layer serves as a source/drain.

30. The method of fabricating the semiconductor device as claimed in claim 29, wherein the source/drain is formed by photolithography/etching.

31. The method of fabricating the semiconductor device as claimed in claim 1, wherein before forming the PAN dielectric layer, comprising:
dissolving an conductive polymer powder in a third solvent to form an conductive polymer solution;
forming the conductive polymer solution on the substrate;
removing the solvent in the conductive polymer solution and forming a conductive polymer layer on the substrate; and
the conductive polymer layer is between the substrate and the PAN dielectric layer.

32. The method of fabricating the semiconductor device as claimed in claim 31, wherein the third solvent is isopropylalcohol (IPA) or ethanol.

33. The method of fabricating the semiconductor device as claimed in claim 31, wherein the conductive polymer solution is formed on the substrate by spin-coating, inkjet-printing, casting, roll-to-roll printing or evaporation.

34. The method of fabricating the semiconductor device as claimed in claim 31, wherein the conductive polymer solution has a weight concentration of about 0.5 wt % to about 20 wt % of the conductive polymer.

35. The method of fabricating the semiconductor device as claimed in claim 31, wherein the conductive polymer layer has a thickness of about 40 nm to 200 nm.

36. The method of fabricating the semiconductor device as claimed in claim 31, wherein the conductive polymer layer is ethylene glycol-doped poly(3,4-ethylenedioxy-thiophene)/poly(styrenesulfonate) (PEDOT:PSS+EG).

37. The method of fabricating the semiconductor device as claimed in claim 31, wherein the conductive polymer layer and the patterned conductive layer are served as a bottom electrode and a top electrode.

38. The method of fabricating the semiconductor device as claimed in claim 37, wherein the patterned conductive layer is formed by photolithography/etching.
